(19) United States
(12) Patent Application Publication
(10) Pub. No.: US 2026/0282634 A1
(43) Pub. Date: Sep. 17, 2026

(54) ELECTRONIC DEVICE

(71) Applicant: Innolux Corporation, Miaoli County (TW)

(72) Inventors: Yi-Cheng Tsai, Miaoli County (TW); Yu-Wei Tu, Miaoli County (TW); Yung-Hsun Wu, Miaoli County (TW)

(73) Assignee: Innolux Corporation, Miaoli County (TW)

(21) Appl. No.: 19/549,004

(22) Filed: Feb. 25, 2026

(30) Foreign Application Priority Data
Mar. 12, 2025 (CN) 202510291402.X

(51) Int. Cl. H10H 29/49

(52) U.S. Cl. CPC H10H 29/49

(57) ABSTRACT

The present disclosure provides an electronic device at least one transmission region and at least one pixel region. The electronic device includes a substrate, two adjacent gate lines extending along a first direction on the substrate, and two adjacent data lines on the substrate, wherein a region enclosed by two adjacent gate lines and two adjacent data lines overlaps with the transmission region and the pixel region. There is a center line extending along the first direction between two adjacent gate lines. In a second direction perpendicular to the first direction, the two adjacent gate lines are distance from each other by a first distance (D), a center of the pixel region is distance from the center line by a second distance (d), and the first distance (D) and the second distance (d) satisfy Formula 1: 0≤d≤0.3*D.

### CROSS-REFERENCE TO RELATED APPLICATION

This application claims the priority benefit of China application serial no. 202510291402.X, filed on Mar. 12, 2025. The entirety of the above-mentioned patent application is hereby incorporated by reference herein and made a part of this specification.

### BACKGROUND

### Technical Field

The present disclosure relates to an electronic device, and particularly relates to an electronic device having a transmission region and a pixel region.

### Description of Related Art

While transparent displays allow users to view the scenery behind them, the periodic arrangement of internal components, such as pixels and circuits, causes light diffraction that blurs the observed scenery. This blurring effect is exacerbated by bright light sources in the background, which can severely impact the viewing experience.

### SUMMARY

According to an embodiment of the present disclosure, an electronic device having at least one transmission region and at least one pixel region includes a substrate, two adjacent gate lines, and two adjacent data lines. The two adjacent gate lines extend along a first direction on the substrate. The two adjacent data lines are on the substrate, and a region surrounded by the two adjacent gate lines and the two adjacent data lines overlaps with one of the at least one transmission region and one of the at least one pixel region. There is a center line extending along the first direction between the two adjacent gate lines, the two adjacent gate lines are at a first distance from each other in a second direction perpendicular to the first direction, a center of the pixel region is at a second distance from the center line in the second direction, and the first distance and the second distance satisfy the following Equation 1. In Equation 1, D is the first distance, and d is the second distance.

0≤D≤0.3*D (1)

According to an embodiment of the present disclosure, an electronic device has two adjacent transmission regions and two adjacent pixel regions and includes a substrate, a first gate line, and a second gate line. The first gate line is between the two adjacent transmission regions and between the two adjacent pixel regions and extends along a first direction. The second gate line is adjacent to the first gate line and is between the two adjacent transmission regions and between the two adjacent pixel regions, wherein the first gate line is electrically connected to the two adjacent pixel regions, the second gate line is electrically connected to the two adjacent pixel regions,

To make the features and advantages of the disclosure more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A is a schematic top view of an electronic device according to a first embodiment of the present disclosure.

FIG. 1B is a schematic cross-sectional view taken along line A-A′ of FIG. 1A according to an embodiment of the present disclosure.

FIG. 2A is a schematic top view of an electronic device according to a second embodiment of the present disclosure.

FIG. 2B is a schematic cross-sectional view taken along line A-A′ of FIG. 2A according to an embodiment of the present disclosure.

FIG. 3A is a schematic top view of an electronic device according to a fifth embodiment of the present disclosure.

FIG. 3B is a schematic cross-sectional view taken along line A-A′ of FIG. 3A according to an embodiment of the present disclosure.

FIG. 4A is a schematic top view of an electronic device according to a seventh embodiment of the present disclosure.

FIG. 4B is a schematic cross-sectional view taken along line A-A′ of FIG. 4A according to an embodiment of the present disclosure.

FIG. 5A is a schematic top view of an electronic device according to a ninth embodiment of the present disclosure.

FIG. 5B is a schematic cross-sectional view taken along line A-A′ of FIG. 5A according to an embodiment of the present disclosure.

### DESCRIPTION OF THE EMBODIMENTS

The disclosure can be understood with reference to the following detailed description in conjunction with the accompanying drawings. It should be noted that, for ease of understanding by readers and for the concision of the illustration, a plurality of drawings in the disclosure only depict parts of the electronic device, and certain elements in the drawings are not drawn according to the actual scale. In addition, the number and size of each element in the drawings are for illustration only, and are not intended to limit the scope of the disclosure.

Certain terms may be used throughout the disclosure and the claims to refer to specific elements. Those skilled in the art will understand that electronic device manufacturers may refer to the same elements by different names. The disclosure does not intend to distinguish between elements that have the same function but have different names. In the following description and claims, the words such as “having” and “including” are open-ended words, and thus should be interpreted as the meaning of “including but not limited to.”

It should be understood that when an element or a film layer is referred to as being “disposed on” or “connected to” another element or film layer, the element or the film layer may be directly on or connected to the another element or film layer, or intervening elements or film layers may also be present in between (non-direct circumstances). In contrast, when an element or film layer is referred to as being “directly on” or “directly connected to” another element or film layer, no intervening elements or film layers are present in between. In addition, when the element or film layer is referred to as overlapping with another element, the element or film layer at least partially overlaps with another element or film layer.

In the embodiments provided later, the same or similar reference numerals are used to refer to the same or similar elements, and the descriptions will not be repeated. In addition, as long as the features of the various embodiments do not depart from or conflict with the spirit of the disclosure, the embodiments may be mixed and matched as desired. It is intended that the disclosure covers modifications and variations provided that they fall within the scope of the following claims and their equivalents. That is, in the following embodiments, technical features in several different embodiments may be replaced, reorganized, and mixed to complete other embodiments without departing from the spirit of the disclosure. Moreover, the terms such as “first” and “second” mentioned in the specification or the claims are only used to name different elements or to distinguish different embodiments or scopes, and are not intended to limit the upper or lower limit of the number of the elements, nor are they intended to limit the manufacturing order or disposition order of the elements.

The electronic device of the present disclosure may be applied to light emitting devices, display devices, but is not limited thereto. The electronic device includes rollable or flexible electronic devices, but is not limited thereto. The display device may include, for example, liquid crystal, light emitting diode (LED), other suitable materials, or combinations thereof. The light emitting diode may include, for example, organic light emitting diode (OLED), micro-LED, mini-LED or quantum dot light emitting diode (QLED, QDLED), but is not limited thereto.

The exemplary embodiments of this disclosure are described in the following for example, and the same reference numerals used in the figures and descriptions are represented to the same or similar portions.

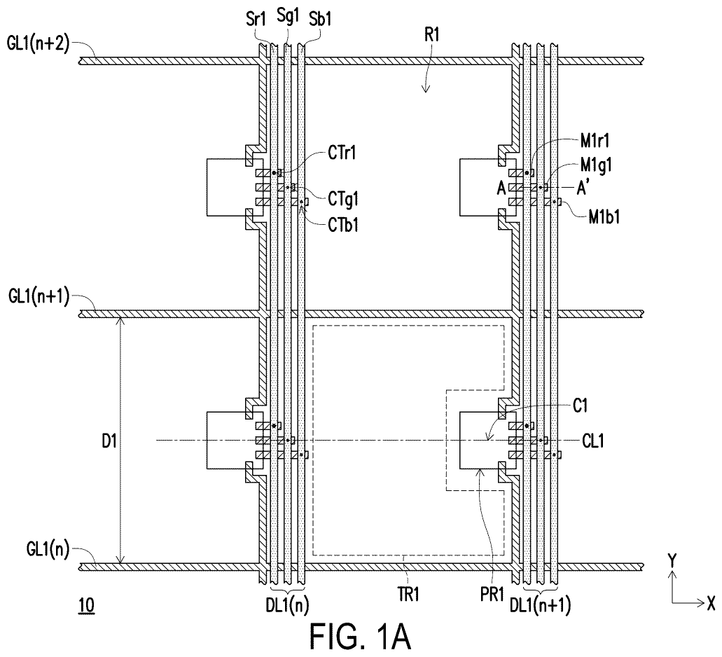

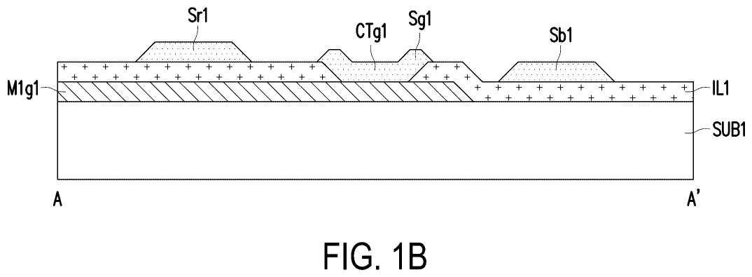

FIG. 1A is a schematic top view of an electronic device according to a first embodiment of the present disclosure. FIG. 1B is a schematic cross-sectional view taken along line A-A′ of FIG. 1A according to an embodiment of the present disclosure.

Referring to FIG. 1A and FIG. 1B, the electronic device 10 has at least one transmission region TR1 and at least one pixel region PR1, and includes a substrate SUB1, two adjacent gate lines (e.g., two adjacent gate lines GL1(n), GL1(n+1) among gate lines GL1(n), GL1(n+1), GL1(n+2)) and two adjacent data lines (e.g., data lines DL1(n), DL1(n+1)).

The transmission region TR1 is a region where the ambient light can pass, and regions with light-blocking films (e.g., light-shielding layers), wirings (e.g., data lines), and components (e.g., active components) are not included in the transmission region as defined in this embodiment. In this embodiment, the pixel region PR1 may include at least a light-emitting unit (not shown) and an active component (not shown) electrically connected to the light-emitting unit. In some embodiments, the data lines DL1(n), DL1(n+1) may provide data signals to the pixel region PR1 through the switching transistors, while the gate lines GL1(n)-GL1(n+2) may provide scanning pulse signals to the pixel regions PR1, and may operate with the switching transistors to control the pixel regions PR1.

The substrate SUB1 may include a transparent material such as a glass or flexible substrate. The two adjacent gate lines GL1(n), GL1(n+1) extend along a first direction (e.g., X direction) on the substrate SUB1. The two adjacent data lines DL1(n), DL1(n+1) are on the substrate SUB1. In some embodiments, the two adjacent data lines DL1(n), DL1(n+1) may extend along a second direction (e.g., Y direction) different from the first direction.

In this embodiment, the gate line shared by two adjacent rows of the pixel regions PR1 (e.g., the gate line GL1(n+1) shown in FIG. 1A) may be configured between the two adjacent rows of the pixel regions PR1, which can reduce the total number of the gate lines GL1(n+1) between the gate lines GL1(n) and GL1(n+2) to increase the ratio of the transmission region TR1 of the electronic device 10, and thereby improving the related problems caused by the diffraction effects. On the other hand, the total number of the gate lines GL1(n)-GL1(n+2) and the data lines DL1(n), DL1(n+1) crossing each other can be reduced accordingly, and the parasitic capacitance can be decreased as well. Therefore, without changing the design value of the resistance-capacitance (RC) product (R*C), the line widths of the gate lines GL1(n)-GL1(n+2) and the data lines DL1(n), DL1(n+1) can be further reduced, so as to be beneficial to increase the ratio of the transmission region TR1 of the electronic device 10.

In this embodiment, the two adjacent gate lines GL1(n), GL1(n+1) may be electrically connected to the pixel region PR1 in the region R1 enclosed by the two adjacent gate lines GL1(n), GL1(n+1) and the two adjacent data lines DL1(n), DL1(n+1).

In this embodiment, there is a center line CL1 extending along the first direction (e.g., X direction) between the two adjacent gate lines GL1(n), GL1(n+1). In the second direction (e.g., Y direction) perpendicular to the first direction, the two adjacent gate lines GL1(n), GL1(n+1) are at a first distance (e.g., a distance D1) from each other, and the center C1 of the pixel region PR1 is at a second distance from the center line CL1, wherein the first distance and the second distance satisfy the following Equation 1:

0≤D≤0.3*d (1)

in Equation 1, D is the first distance, and d is the second distance.

In some embodiments, the upper limit value in Equation 1 may be 0.25*D. In some other embodiments, the upper limit value in Equation 1 may be 0.2*D. In some alternative embodiments, the upper limit value in Equation 1 may be 0.1*D.

In some embodiments, each of the data lines DL1(n), DL1(n+1) may include sub-data lines Sr1, Sg1, Sb1. In some embodiments, as shown in FIG. 1A and FIG. 1B, the sub-data lines Sr1, Sg1, Sb1 on the insulation layer IL1 may be electrically connected to the pixel region PR1 through contacts CTr1, CTg1, CTb1 that penetrate through the insulation layer IL1 and wirings M1r1, M1g1, M1b1 under the insulation layer IL1. The sub-data lines Sr1, Sg1, Sb1 and the wirings M1r1, M1g1, M1b1 may include any suitable conductive materials such as metals, but are not limited thereto. The insulation layer IL1 may include any suitable insulating material. According to some embodiments, the insulation layer IL1 may include inorganic materials, organic materials, or combinations thereof, but is not limited thereto. According to some embodiments, the inorganic materials may include silicon nitride, silicon oxide, silicon oxynitride, aluminum oxide, other suitable materials, or combinations thereof, but are not limited thereto.

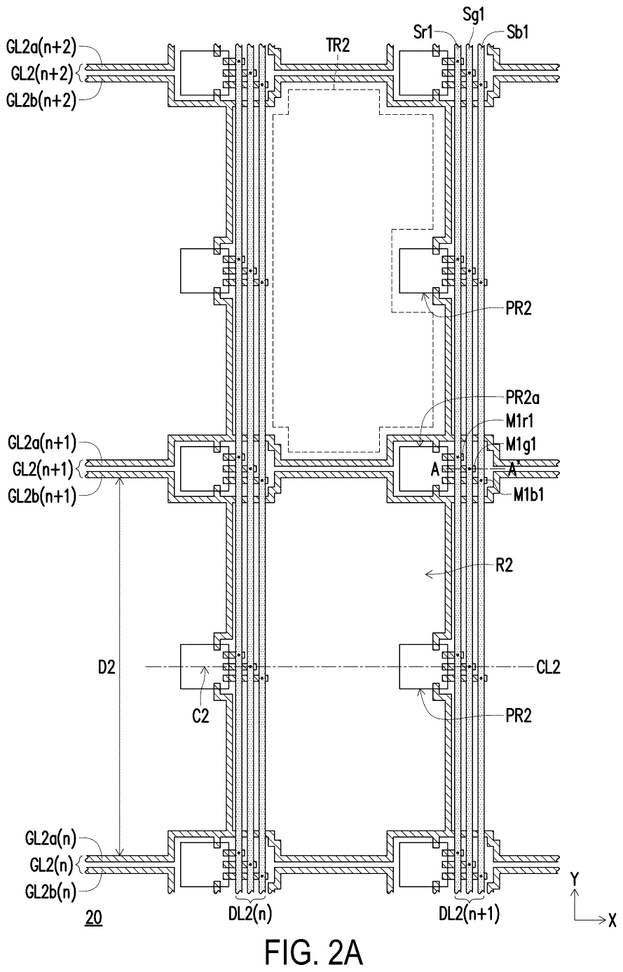

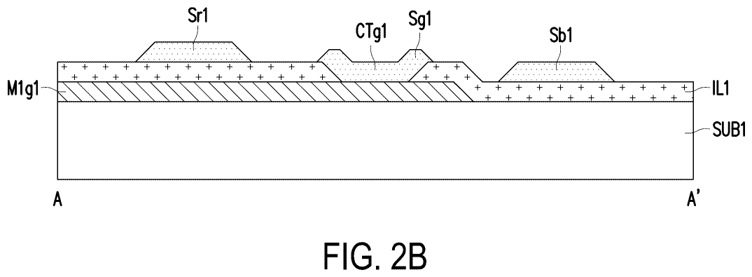

FIG. 2A is a schematic top view of an electronic device according to a second embodiment of the present disclosure. FIG. 2B is a schematic cross-sectional view taken along line A-A′ of FIG. 2A according to an embodiment of the present disclosure. The electronic device 20 shown in FIG. 2A is similar to the electronic device 10 shown in FIG. 1A. The main differences therebetween are that the configurations of gate lines GL2(n), GL2(n+1), GL2(n+2), data lines DL2(n), DL2(n+1), transmission regions TR2, and pixel regions PR2 of the electronic device 20 are different from the configurations of the gate lines GL1(n)-GL1(n+2), the data lines DL1(n), DL1(n+1), the transmission regions TR1, and the pixel regions PR1 of the electronic device 10. Other identical or similar components are represented by the same or similar reference numerals and will not be repeated here.

Referring to FIG. 2A and FIG. 2B, the electronic device 20 has at least one transmission region TR2 and at least one pixel region PR2, and includes a substrate SUB1, two adjacent gate lines (e.g., two adjacent gate lines GL2(n), GL2(n+1) among the gate lines GL2(n)-GL2(n+2)) and two adjacent data lines (e.g., data lines DL2(n), DL2(n+1)). In some embodiments, the data lines DL1(n), DL1(n+1) may provide data signals to the pixel regions PR2 through active components (e.g., switching transistors) in the pixel regions PR2, while the gate lines GL2(n)-GL2(n+2) may provide scanning pulse signals to the pixel regions PR2, and may operate with the switching transistors to control the pixel regions PR2. In some embodiments, the electronic device 20 may include a plurality of transmission regions TR2 arranged in parallel in the first direction and/or in the second direction (e.g., X direction and/or Y direction). In some embodiments, the electronic device 20 may include a plurality of pixel regions PR2 arranged in parallel in the first direction and/or in the second direction (e.g., X direction and/or Y direction).

In this embodiment, the electronic device 20 also includes another pixel region PR2a adjacent to the pixel region PR2 in the second direction (e.g., Y direction). In some embodiments, another pixel region PR2a may be configured between the pixel regions PR2 adjacent to each other in the second direction.

The two adjacent gate lines GL2(n), GL2(n+1) extend along a first direction (e.g., X direction) on the substrate SUB1. The two adjacent data lines DL2(n), DL2(n+1) are on the substrate SUB1. In some embodiments, the two adjacent data lines DL2(n), DL2(n+1) may extend along a second direction (e.g., Y direction) different from the first direction. In some embodiments, each of the gate lines GL2(n), GL2(n+1), or GL2(n+2) may include a first sub-gate line GL2a(n), GL2a(n+1), or GL2a(n+2) and a second sub-gate line GL2b(n), GL2b(n+1), or GL2b(n+2) adjacent to each other. In some embodiments, another pixel region PR2a may be configured in a region surrounded by the first sub-gate line GL2a(n+1) and the second sub-gate line GL2b(n+1) adjacent to each other.

In this embodiment, the gate line shared by the two adjacent rows of the pixel regions PR2 (e.g., the gate line GL2(n+1) shown in FIG. 2A) may be configured between the two adjacent rows of the pixel regions PR2, which can reduce the total number of the gate lines GL2(n)-GL2(n+2) to increase the ratio of the transmission region TR2 of the electronic device 20, and thereby improving the related problems caused by the diffraction effects. On the other hand, the total number of the gate lines GL2(n)-GL2(n+2) and the data lines DL2(n), DL2(n+1) crossing each other can be reduced accordingly, and the parasitic capacitance can be decreased as well. Therefore, under the condition that the RC product (R*C) design value remains unchanged, the line widths of the gate lines GL2(n)-GL2(n+2) and the data lines DL2(n), DL2(n+1) can be further reduced, so as to be beneficial for increasing the ratio of the transmission region TR2 of the electronic device 20.

In some embodiments, the straight segments of each gate line GL2(n)-GL2(n+2) and each data line DL2(n), DL2(n+1) may be adjusted to curves, so as to adjust the diffraction pattern by adjusting the detailed contour of the transmission region TR2. As a result, it is beneficial for improving the blurring phenomenon caused by the diffraction effects.

In this embodiment, in the case where the electronic device 20 includes another pixel region PR2a adjacent to the pixel region PR2 in the second direction (e.g., Y direction), the pixel unit may include the transmission region TR2 and the pixel region PR2 overlapping with the region R2, a portion (e.g., the lower portion) of another pixel region PR2a overlapping with the region surrounded by the first sub-gate line GL2a(n+1) and the second sub-gate line GL2b(n+1), and a portion (e.g., the upper portion) of another pixel region PR2a overlapping with the region surrounded by the first sub-gate line GL2a(n) and the second sub-gate line GL2b(n). That is, each pixel unit may include one transmission region TR2, one pixel region PR2, and portions of two other pixel regions PR2a adjacent to the pixel region PR2. When considering the area occupied by one pixel region PR2 as one pixel, in the above-mentioned pixel unit, every two pixels may correspond to one transmission region TR2, which is beneficial for increasing the ratio of the transmission region TR2 and the space period of the electronic device 20, and thus is beneficial for improving the related problems caused by the diffraction effects.

In this embodiment, the two adjacent gate lines GL2(n), GL2(n+1) may be electrically connected to the pixel region PR2 in the region R2 surrounded by the two adjacent gate lines GL2(n), GL2(n+1) and the two adjacent data lines DL2(n), DL2(n+1). Specifically, the first sub-gate line GL2a(n) of the gate line GL2(n) and the second sub-gate line GL2b(n+1) of the gate line GL2(n+1) are electrically connected to the pixel region PR2. In this embodiment, one of the two adjacent gate lines GL2(n), GL2(n+1) (e.g., a gate line GL2(n) or a gate line GL2(n+1)) may be electrically connected to another pixel region PR2a. Specifically, the first sub-gate line GL2a(n+1) and the second sub-gate line GL2b(n+1) of the gate line GL2(n+1) are electrically connected to another pixel region PR2a.

In this embodiment, there is a center line CL2 extending along the first direction (e.g., X direction) between the two adjacent gate lines GL2(n), GL2(n+1) among the gate lines GL2(n)-GL2(n+2). In the second direction (e.g., Y direction) perpendicular to the first direction, the two adjacent gate lines GL2(n), GL2(n+1) are at a first distance (e.g., a distance D2) from each other, and the center C2 of the pixel region PR2 is at a second distance from the center line CL2, wherein the first distance and the second distance satisfy the following Equation 1:

0≤D≤0.3*d (1)

in Equation 1, D is the first distance, and d is the second distance.

In some embodiments, the upper limit value in Equation 1 may be 0.25*D. In some other embodiments, the upper limit value in Equation 1 may be 0.2*D. In some alternative embodiments, the upper limit value in Equation 1 may be 0.1*D.

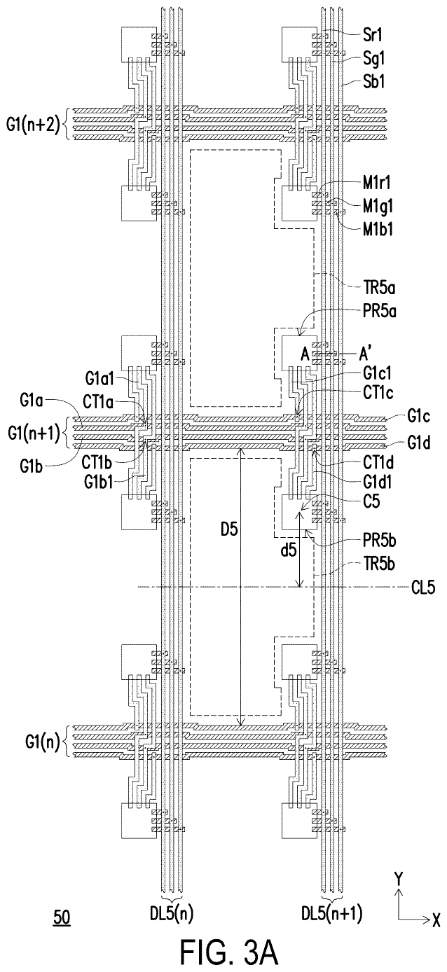

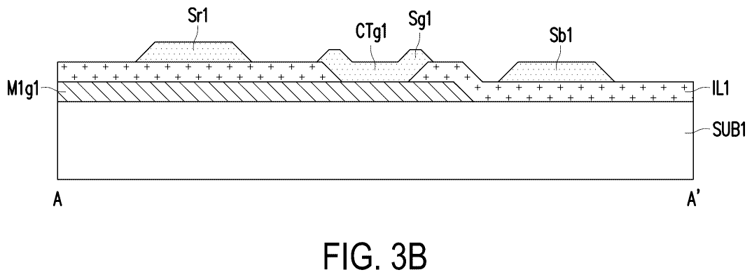

FIG. 3A is a schematic top view of an electronic device according to a fifth embodiment of the present disclosure. FIG. 3B is a schematic cross-sectional view taken along line A-A′ of FIG. 3A according to an embodiment of the present disclosure. The electronic device 50 shown in FIG. 3A is similar to the electronic device 10 shown in FIG. 1A. The main differences therebetween are that the configurations of gate lines G1(n), G1(n+1), G1(n+2), data lines DL5(n), DL5(n+1), transmission regions TR5a, TR5b, and pixel regions PR5a, PR5b of the electronic device 50 are different from the configurations of the gate lines GL1(n)-GL1(n+2), the data lines DL1(n), DL1(n+1), the transmission regions TR1, and the pixel regions PR1 of the electronic device 10. Other identical or similar components are represented by the same or similar reference numerals and will not be repeated here.

Referring to FIG. 3A and FIG. 3B, the electronic device 50 has two adjacent transmission regions TR5a, TR5b and two adjacent pixel regions PR5a, PR5b, and includes a substrate SUB1, a first gate line (e.g., a first gate line G1a included in each of the gate lines G1(n)-G1(n+2)) and a second gate line (e.g., a second gate line G1b included in each of the gate lines G1(n)-G1(n+2)).

In some embodiments, the electronic device 50 may include a plurality of transmission regions TR5a, TR5b arranged in parallel in the first direction and/or in the second direction (e.g., X direction and/or Y direction). In other words, a pair of transmission regions TR5a, TR5b including the two adjacent transmission regions TR5a, TR5b may be configured as multiple pairs of the transmission regions TR5a, TR5b, and the multiple pairs of the transmission regions TR5a, TR5b are arranged in parallel in the first direction and/or in the second direction (e.g., X direction and/or Y direction). In some embodiments, the electronic device 50 may include a plurality of pixel regions PR5a, PR5b arranged in parallel in the first direction and/or in the second direction (e.g., X direction and/or Y direction). In other words, a pair of pixel regions PR5a, PR5b including the two adjacent pixel regions PR5a, PR5b may be configured as multiple pairs of the pixel regions PR5a, PR5b, and the multiple pairs of the pixel regions PR5a, PR5b are arranged in parallel in the first direction and/or in the second direction (e.g., X direction and/or Y direction).

In this embodiment, the gate lines G1(n)-G1(n+2) extend along a first direction (e.g., X direction) on the substrate SUB1. In some embodiments, each of the gate lines G1(n)-G1(n+2) may include a first gate line G1a, a second gate line G1b, a third gate line G1c, and a fourth gate line G1d. In this embodiment, the data lines DL5(n), DL5(n+1) extend along a second direction (e.g., Y direction) on the substrate SUB1. In some embodiments, each of the data lines DL5(n), DL5(n+1) may include sub-data lines Sr1, Sg1, Sb1.

The first gate line G1a is between the two adjacent transmission regions TR5a, TR5b and the two adjacent pixel regions PR5a, PR5b, and extends along the first direction (e.g., X direction). The second gate line G1b is adjacent to the first gate line G1a and is between the two adjacent transmission regions TR5a, TR5b and the two adjacent pixel regions PR5a, PR5b. In this embodiment, the first gate line G1a is electrically connected to the two adjacent pixel regions PR5a, PR5b, the second gate line G1b is electrically connected to the two adjacent pixel regions PR5a, PR5b, and a portion of the first gate line G1a crosses a portion of the second gate line G1b, thereby reducing the total number of the gate lines G1(n)-G1(n+2), increasing the ratio of the transmission regions TR5a, TR5b of the electronic device 50, and reducing the total number of the gate lines G1(n)-G1(n+2) and the data lines DL5(n), DL5(n+1) crossing each other, which are beneficial for improving the related problems caused by the diffraction effects (such as the blurring phenomenon generated on the observed scenery). As such, when the total number of crossings is reduced, the parasitic capacitance also decreases accordingly. Therefore, under the condition that the RC product (R*C) design value remains unchanged, the line widths of the gate lines G1(n)-G1(n+2) and the data lines DL5(n), DL5(n+1) can be further reduced, which is beneficial for increasing the ratio of the transmission regions TR5a, TR5b of the electronic device 50.

In some embodiments, as shown in FIG. 3A, a portion of the first gate line G1a (e.g., a segment G1a1 of the first gate line G1a) crosses a portion of the second gate line G1b. In some other embodiments, a portion of the second gate line G1b (e.g., a segment G1b1 of the second gate line G1b) crosses a portion of the first gate line G1a. In some embodiments, the first gate line G1a connects to the segment G1a1 through a contact CT1a and then electrically connects to the two adjacent pixel regions PR5a, PR5b through the segment G1a1. In some embodiments, the second gate line G1b connects to a segment G1b1 through a contact CT1b and then electrically connects to the two adjacent pixel regions PR5a, PR5b through the segment G1b1.

In some embodiments, the third gate line G1c may connect to a segment G1c1 through contact CT1c and then electrically connect to the pixel region PR5a through the segment G1c1. In some embodiments, the fourth gate line G1d may connect to a segment G1d1 through a contact CT1d and then electrically connect to the pixel region PR5b through the segment G1d1.

In this embodiment, as shown in FIG. 3A, the pixel unit may include a transmission region TR5b and pixel regions PR5a, PR5b that overlap with the area enclosed by the two adjacent gate lines G1(n), G1(n+1) and the two adjacent data lines DL5(n), DL5(n+1). That is, each pixel unit may include one transmission region TR5b and two pixel regions PR5a, PR5b. When considering the area occupied by one pixel region PR5a (or PR5b) as one pixel, in the above-mentioned pixel unit, every two pixels correspond to one transmission region TR5a (or TR5b), which can be beneficial for increasing the ratio and space period of the transmission regions TR5a, TR5b of the electronic device 50, and thus is beneficial for improving the related problems caused by the diffraction effects.

In some embodiments, there is a center line CL5 extending along the first direction (e.g., X direction) between the two adjacent gate lines G1(n) and G1(n+1) among the gate lines G1(n)-G1(n+2). In the second direction (e.g., Y direction) perpendicular to the first direction, the two adjacent gate lines G1(n), G1(n+1) are at a first distance (e.g., a distance D5) from each other, and the center C5 of the pixel region PR5b is at a second distance (e.g., a distance d5) from the center line CL5, wherein the first distance and the second distance satisfy the following Equation 1:

0≤D≤0.3*d (1)

in Equation 1, D is the first distance, and d is the second distance.

In some embodiments, the upper limit value in Equation 1 may be 0.25*D. In some other embodiments, the upper limit value in Equation 1 may be 0.2*D. In some alternative embodiments, the upper limit value in Equation 1 may be 0.1*D.

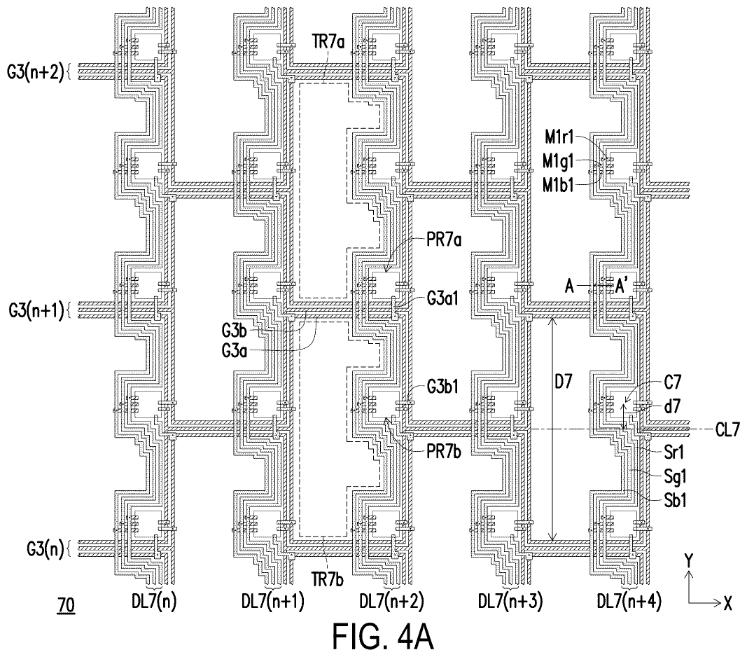

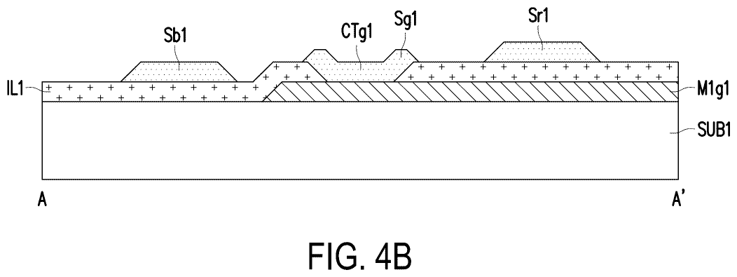

FIG. 4A is a schematic top view of an electronic device according to a seventh embodiment of the present disclosure. FIG. 4B is a schematic cross-sectional view taken along line A-A′ of FIG. 4A according to an embodiment of the present disclosure. The electronic device 70 shown in FIG. 4A is similar to the electronic device 50 shown in FIG. 3A, and the main differences therebetween are that the configurations of gate lines G3(n), G3(n+1), G3(n+2), data lines DL7(n), DL7(n+1), DL7(n+2), DL7(n+3), DL7(n+4), transmission regions TR7a, TR7b and pixel regions PR7a, PR7b of the electronic device 70 are different from the configurations of the gate lines G1(n)-G1(n+2), the data lines DL5(n), DL5(n+1), the transmission regions TR5a, TR5b and the pixel regions PR5a, PR5b of the electronic device 50. Other identical or similar components are represented by the same or similar reference numerals and will not be repeated here.

Referring to FIG. 4A and FIG. 4B, the electronic device 70 has two adjacent transmission regions TR7a, TR7b and two adjacent pixel regions PR7a, PR7b, and includes a substrate SUB1, a first gate line (e.g., a first gate line G3a included in each of the gate lines G3(n)-G3(n+2)) and a second gate line (e.g., a second gate line G3b included in each of the gate lines G3(n)-G3(n+2)).

In this embodiment, the electronic device 70 may include a plurality of transmission regions TR7a, TR7b arranged alternately in the first direction and/or in the second direction (e.g., X direction and/or Y direction). In other words, a pair of transmission regions TR7a, TR7b including the two adjacent transmission regions TR7a, TR7b may be configured as multiple pairs of the transmission regions TR7a, TR7b, and the multiple pairs of the transmission regions TR7a, TR7b are arranged alternately in the first direction and/or in the second direction (e.g., X direction and/or Y direction), so that the transmission regions TR7a, TR7b are arranged alternately at positions of different columns and/or rows, and therefore the diffraction pattern can be adjusted according to different needs to improve the blurring phenomenon caused by the diffraction effects in response to the different needs. In some embodiments, the electronic device 70 may include a plurality of pixel regions PR7a, PR7b arranged in parallel in the first direction and/or in the second direction (e.g., X direction and/or Y direction). In other words, a pair of pixel regions PR7a, PR7b including the two adjacent pixel regions PR7a, PR7b may be configured as multiple pairs of the pixel regions PR7a, PR7b, and the multiple pairs of the pixel regions PR7a, PR7b are arranged in parallel in the first direction and/or in the second direction (e.g., X direction and/or Y direction).

In this embodiment, the gate lines G3(n)-G3(n+2) extend along the first direction (e.g., X direction) on the substrate SUB1. In some embodiments, each of the gate lines G3(n)-G3(n+2) may include a first gate line G3a and a second gate line G3b. In this embodiment, the data lines DL7(n)-DL7(n+4) extend along the second direction (e.g., Y direction) on the substrate SUB1.

The first gate line G3a is between the two adjacent transmission regions TR7a, TR7b and the two adjacent pixel regions PR7a, PR7b, and extends along the first direction (e.g., X direction). The second gate line G3b is adjacent to the first gate line G3a and is between the two adjacent transmission regions TR7a, TR7b and between the two adjacent pixel regions PR7a, PR7b. In this embodiment, the first gate line G3a is electrically connected to the two adjacent pixel regions PR7a, PR7b, the second gate line G3b is electrically connected to the two adjacent pixel regions PR7a, PR7b, and a portion of the first gate line G3a crosses a portion of the second gate line G3b. In this way, the ratio of the transmission regions TR7a, TR7b of the electronic device 70 can be improved and the total number of the gate lines G3(n)-G3(n+2) and the data lines DL7(n)-DL7(n+4) crossing each other can be reduced, so as to be beneficial for improving the related problems caused by the diffraction effects (such as the blurring phenomenon generated on the observed scenery). On the other hand, the parasitic capacitance can be decreased as well as the total number of crossings is reduced accordingly. Therefore, under the condition that the RC product (R*C) design value remains unchanged, the line widths of t he gate lines G3(n)-G3(n+2) and the data lines DL7(n)-DL7(n+4) can be further reduced, which is beneficial for increasing the ratio of the transmission regions TR7a, TR7b of the electronic device 70.

In some embodiments, as shown in FIG. 4A, a portion of the first gate line G3a (e.g., segment G3a1 of the first gate line G3a) crosses a portion of the second gate line G3b. In some other embodiments, a portion of the second gate line G3b (e.g., a segment G3b1 of the second gate line G3b) crosses a portion of the first gate line G3a. In some embodiments, the first gate line G3a may be connected to the segment G3a1 through a contact and then electrically connected to the pixel region PR7a through the segment G3a1, while the first gate line G3a may be connected to another segment through another contact and then electrically connected to the pixel region PR7b through that segment. In some embodiments, the second gate line G3b may be connected to the segment G3b1 through a contact and then electrically connected to the pixel region PR7b through the segment G3b1, while the second gate line G3b may be connected to another segment through another contact and then electrically connected to the pixel region PR7a through that segment.

In this embodiment, as shown in FIG. 4A, each pixel unit may include one transmission region TR7b and two pixel regions PR7a, PR7b. When considering the area occupied by one pixel region PR7a (or PR7b) as one pixel, in the above-mentioned pixel unit, every two pixels may correspond to one transmission region TR7a (or TR7b), which is beneficial for increasing the ratio and space period of the transmission regions TR7a, TR7b of the electronic device 70, and thus is beneficial for improving the related problems caused by the diffraction effects.

In some embodiments, the segments of the gate lines G3(n)-G3(n+2) extending in the second direction (e.g., Y direction) are different from the data lines DL7(n)-DL7(n+4), which is beneficial for increasing the ratio of transmission regions TR7a, TR7b of the electronic device 70 by reducing the line spacing.

In some embodiments, there is a center line CL7 extending along the first direction (e.g., X direction) between the two adjacent gate lines G3(n), G3(n+1). In the second direction (e.g., Y direction) perpendicular to the first direction, the two adjacent gate lines G3(n), G3(n+1) are at a first distance (e.g., distance D7) from each other, and the center C7 of the pixel region PR7b is at a second distance (e.g., distance d7) from the center line CL7, wherein the first distance and the second distance satisfy the following Equation 1:

0≤D≤0.3*d (1)

in Equation 1, D is the first distance, and d is the second distance.

In some embodiments, the upper limit value in Equation 1 may be 0.25*D. In some other embodiments, the upper limit value in Equation 1 may be 0.2*D. In some alternative embodiments, the upper limit value in Equation 1 may be 0.1*D.

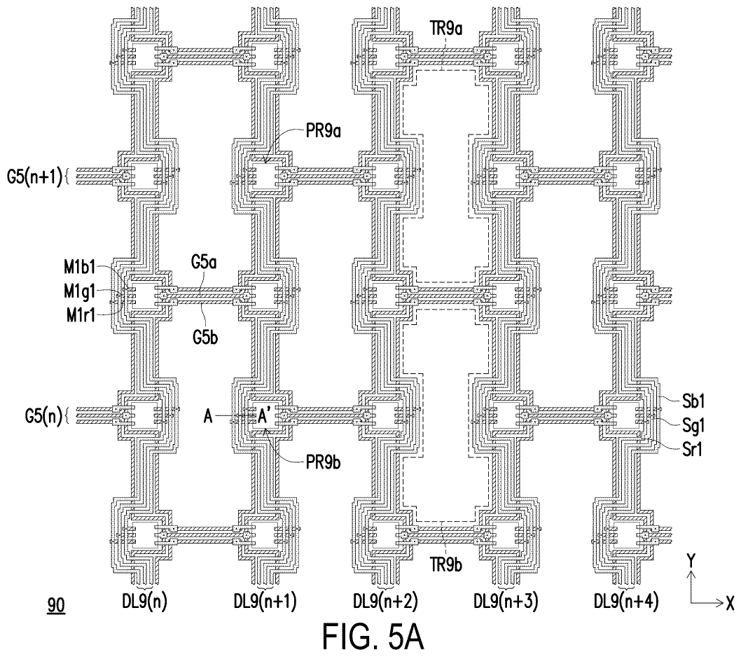

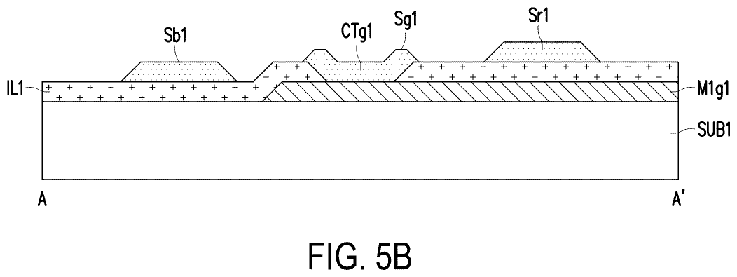

FIG. 5A is a schematic top view of an electronic device according to a ninth embodiment of the present disclosure. FIG. 5B is a schematic cross-sectional view taken along line A-A′ of FIG. 5A according to an embodiment of the present disclosure. The electronic device 90 shown in FIG. 5A is similar to the electronic device 50 shown in FIG. 3A, and the main differences therebetween are that the configurations of gate lines G5(n), G5(n+1), data lines DL9(n), DL9(n+1), DL9(n+2), DL9(n+3), DL9(n+4), transmission regions TR9a, TR9b and pixel regions PR9a, PR9b of the electronic device 90 are different from the configurations of the gate lines G1(n)-G1(n+2), the data lines DL5(n), DL5(n+1), the transmission regions TR5a, TR5b and the pixel regions PR5a, PR5b of the electronic device 50. Other identical or similar components are represented by the same or similar reference numerals, and will not be repeated here.

Referring to FIG. 5A and FIG. 5B, the electronic device 90 has two adjacent transmission regions TR9a, TR9b and two adjacent pixel regions PR9a, PR9b, and includes a substrate SUB1, a first gate line (e.g., a first gate line G5a included in each of the gate lines G5(n), G5(n+1)) and a second gate line (e.g., a second gate line G5b included in each of the gate lines G5(n), G5(n+1)).

In this embodiment, the electronic device 90 may include a plurality of transmission regions TR9a, TR9b arranged alternately in the first direction and/or in the second direction (e.g., X direction and/or Y direction). In other words, a pair of transmission regions TR9a, TR9b including the two adjacent transmission regions TR9a, TR9b may be configured as multiple pairs of the transmission regions TR9a, TR9b, and the multiple pairs of the transmission regions TR9a, TR9b are arranged alternately in the first direction and/or in the second direction (e.g., X direction and/or Y direction), so that the transmission regions TR9a, TR9b are arranged alternately at positions of different columns and/or rows, and therefore the diffraction pattern can be adjusted according to different needs to improve the blurring phenomenon caused by the diffraction effects in response to the different needs. In some embodiments, the electronic device 90 may include a plurality of pixel regions PR9a, PR9b arranged in parallel in the first direction and/or in the second direction (e.g., X direction and/or Y direction). In other words, a pair of pixel regions PR9a, PR9b including the two adjacent pixel regions PR9a, PR9b may be configured as multiple pairs of the pixel regions PR9a, PR9b, and the multiple pairs of the pixel regions PR9a, PR9b are arranged in parallel in the first direction and/or in the second direction (e.g., X direction and/or Y direction).

In this embodiment, the gate lines G5(n), G5(n+1) extend along a first direction (e.g., X direction) on the substrate SUB1. In some embodiments, each of the gate lines G5(n), G5(n+1) may include a first gate line G5a and a second gate line G5b. In this embodiment, the data lines DL9(n)-DL9(n+4) extend along a second direction (e.g., Y direction) on the substrate SUB1.

The first gate line G5a is between the two adjacent transmission regions TR9a, TR9b and between the two adjacent pixel regions PR9a, PR9b, and extends along the first direction (e.g., X direction). The second gate line G5b is adjacent to the first gate line G5a and is between the two adjacent transmission regions TR9a, TR9b and between the two adjacent pixel regions PR9a, PR9b. In this embodiment, the first gate line G5a is electrically connected to the two adjacent pixel regions PR9a, PR9b, the second gate line G5b is electrically connected to the two adjacent pixel regions PR9a, PR9b, and a portion of the first gate line G5a crosses a portion of the second gate line G5b, which can improve the ratio of the transmission regions TR9a, TR9b of the electronic device 90 and reduce the total number of the gate lines G5(n), G5(n+1) and the data lines DL9(n)-DL9(n+4) crossing each other, so as to be beneficial for improving the related problems caused by the diffraction effects (such as the blurring phenomenon generated on the observed scenery). On the other hand, the parasitic capacitance can be decreased as well as the total number of the crossings is reduced accordingly. Therefore, under the condition that the RC product (R*C) design value remains unchanged, the line widths of the gate lines G5(n), G5(n+1) and the data lines DL9(n)-DL9(n+4) can be further reduced, so as to be beneficial for increasing the ratio of the transmission regions TR9a, TR9b of the electronic device 90.

In this embodiment, as shown in FIG. 5A, each pixel unit may include one transmission region TR9a (or TR9b) and portions of six pixel regions PR9a (or PR9b). When considering the area occupied by one pixel region PR9a (or PR9b) as one pixel, in the above-mentioned pixel unit, every two pixels may correspond to one transmission region TR9a (or TR9b), which is beneficial for increasing the ratio and space period of the transmission regions TR9a, TR9b of the electronic device 90, and thus is beneficial for improving the related problems caused by the diffraction effects.

In some embodiments, the segments of the gate lines G5(n), G5(n+1) extending in the second direction (e.g., Y direction) are different from the data lines DL9(n)-DL9(n+4), so as to be beneficial for increasing the ratio of the transmission regions TR9a, TR9b of the electronic device 90 by reducing the line spacing.

In summary, in the electronic device of the embodiments of the present disclosure, through the configurations of the gate lines, the data lines, the transmission regions, and the pixel regions, the ratio of the transmission regions of the electronic device can be increased and the total number of the gate lines and the data lines crossing each other can be reduced, and thus it is beneficial for improving the related problems caused by the diffraction effects, so that the display quality of the electronic device can be enhanced.

What is claimed is:

1. An electronic device having at least one transmission region and at least one pixel region and comprising:
a substrate;
two adjacent gate lines extending along a first direction on the substrate; and
two adjacent data lines on the substrate, wherein a region surrounded by the two adjacent gate lines and the two adjacent data lines overlaps with one of the at least one transmission region and one of the at least one pixel region,
wherein, there is a center line extending along the first direction between the two adjacent gate lines, the two adjacent gate lines are at a first distance from each other in a second direction perpendicular to the first direction, a center of the pixel region is at a second distance from the center line in the second direction, and the first distance and the second distance satisfy the following Equation 1:
0≤d≤0.3*D (1)
in Equation 1, D is the first distance, and d is the second distance.

2. The electronic device according to claim 1, wherein the pixel region comprises a plurality of light emitting diodes.

3. The electronic device according to claim 1, wherein the two adjacent gate lines are electrically connected to the pixel region.

4. The electronic device according to claim 1, further comprising an another pixel region adjacent to the pixel region in the second direction, wherein one of the two adjacent gate lines is electrically connected to the another pixel region.

5. The electronic device according to claim 4, wherein each of the two adjacent gate lines comprises a first sub-gate line and a second sub-gate line adjacent to each other, and the another pixel region is configured in a region surrounded by the first sub-gate line and the second sub-gate line.

6. The electronic device according to claim 5, wherein the another pixel region is configured in a region surrounded by the first sub-gate line and the second sub-gate line and one of the two adjacent data lines.

7. The electronic device according to claim 5, wherein the first sub-gate line of one of the two adjacent gate lines and the second sub-gate line of another one of the two adjacent gate lines are electrically connected to the pixel region.

8. The electronic device according to claim 5, wherein the first sub-gate line and the second sub-gate line are electrically connected to the another pixel region.

9. The electronic device according to claim 1, wherein the at least one transmission region comprises a plurality of transmission regions arranged in a staggered manner in the first direction or in the second direction.

10. The electronic device according to claim 9, wherein the at least one pixel region comprises a plurality of pixel regions are arranged in parallel in the first direction or in the second direction.

11. An electronic device having two adjacent transmission regions and two adjacent pixel regions and comprising:
a substrate;
a first gate line between the two adjacent transmission regions, between the two adjacent pixel regions, and extending along a first direction; and
a second gate line adjacent to the first gate line, between the two adjacent transmission regions, and between the two adjacent pixel regions,
wherein the first gate line is electrically connected to the two adjacent pixel regions, the second gate line is electrically connected to the two adjacent pixel regions, and a portion of the first gate line crosses a portion of the second gate line.

12. The electronic device according to claim 11, wherein a pair of transmission regions comprising the two adjacent transmission regions are configured as multiple pairs arranged in a staggered manner in the first direction or in a second direction different from the first direction.

13. The electronic device according to claim 12, wherein a pair of pixel regions comprising the two adjacent pixel regions are configured as multiple pairs arranged in parallel in the first direction or in the second direction.

14. The electronic device according to claim 12, wherein a pair of pixel regions comprising the two adjacent pixel regions are configured as multiple pairs arranged in a staggered manner in the first direction or in the second direction.

15. The electronic device according to claim 11, wherein a pair of gate lines comprising the first gate line and the second gate line are configured as multiple pairs arranged in a second direction perpendicular to the first direction,
wherein, there is a center line extending along the first direction between two adjacent pairs of gate lines among the multiple pairs of gate lines, the two adjacent pairs of gate lines among the multiple pairs of gate lines are at a first distance from each other in the second direction, a center of each of the two adjacent pixel regions are at a second distance from the center line in the second direction, and the first distance and the second distance satisfy the following Equation 1:
0≤d≤0.3*D
in Equation 1, D is the first distance, and d is the second distance.

16. The electronic device according to claim 11, wherein a pair of transmission regions comprising the two adjacent transmission regions are configured as multiple pairs arranged in parallel in the first direction.
